(19) United States
(12) Patent Application Publication
(10) Pub. No.: US 2003/0164998 A1
(43) Pub. Date: Sep. 4, 2003

(54) Ion-assisted deposition techniques for the planarization of topological defects

(75) Inventors: Paul B. Mirkarimi, Sunol, CA (US); Eberhard A. Spiller, Livermore, CA (US); Daniel G. Stearns, Los Altos, CA (US)

Correspondence Address: Alan H. Thompson, Deputy Laboratory Counsel, Lawrence Livermore National Laboratory, P.O. Box 808, L-703, Livermore, CA, 94551-0808, US

(73) Assignee: The Regents of the University of California

(21) Appl. No.: 10/086,614

(22) Filed: Mar. 1, 2002

(51) Int. Cl. B05D 5/06; C23C 14/32

(52) U.S. Cl. 359/237; 427/162; 427/551; 204/192.34; 204/192.11

(57) ABSTRACT

An ion-assisted deposition technique to provide planarization of topological defects, e.g., to mitigate the effects of small particle contaminants on reticles for extreme ultraviolet (EUV) lithography. Reticles for EUV lithography will be fabricated by depositing high EUV reflectance Mo/Si multilayer films on superpolished substrates and topological substrate defects can nucleate unacceptable (“critical”) defects in the reflective Mo/Si coatings. A secondary ion source is used to etch the Si layers in between etch steps to produce topological defects with heights that are harmless to the lithographic process.

The United States Government has rights in this invention pursuant to Contract No. W-7405-ENG-48 between the United States Department of Energy and the University of California for the operation of Lawrence Livermore National Laboratory.

### BACKGROUND OF THE INVENTION P 1. Field of the Invention

The present invention relates to ion-beam polishing of optical materials, and more specifically, it relates to the use of an ion-beam technique for planarizing topological defects.

2. Description of Related Art

The application of ion-assistance/ion polishing, to multilayer coating deposition processes has been extensively reported in the literature over many years. The purpose of this technique, which was applied to Mo/Si as well as other multilayer coating systems, was to reduce the high-spatial frequency roughness of the interfaces and/or surface and in some instances to enhance the reflectivity of the coatings. The use of this technique to smooth or planarize topological substrate defects was not demonstrated or discussed.

Reticle blanks for extreme ultraviolet lithography are fabricated by depositing reflective multilayer coatings such as Mo/Si on superpolished substrates. These reflective reticles are a significant departure from conventional transmission reticles, and the reflective reticles must be nearly defect-free in the sense that there cannot be localized structural imperfections in the coating that perturb the reflected radiation field sufficiently to print at the wafer. Simulations indicate that substrate particles as small as ˜25 nm in diameter could perturb the reflective multilayer enough to print in commercial extreme ultraviolet lithography tools. Consequently it is very important to develop methods to minimize the effect of small particle contaminants on the reflective multilayer film.

If the planarization layer for defect smoothing is to also be used as the reflective layer for applications such as EUVL reticles, then the layer must meet strict thickness uniformity specifications. The conditions for obtaining excellent thickness uniformity usually require off-normal incidence deposition, in which defect smoothing is not optimal.

It has been shown previously that the stress in Mo/Si multilayer films can be made tensile by making the Mo fraction >70%; however, the EUV reflectivity of a high-Mo fraction Mo/Si mulitlayer film is too small. It has also been shown that by using a buffer-layer that has tensile stress, the effect of compressive stress in Mo/Si films can be counteracted. The Mo/Si films grown by physical vapor deposition techniques with a high Mo fraction cannot generally be used as buffer-layers, since the thicker Mo produces a surface that is too rough for extreme ultraviolet (EUV) lithography specifications. This invention provides a method with the potential to produce a Mo/Si film having a high Mo fraction and low roughness and which can be used for EUV lithography applications.

### SUMMARY OF THE INVENTION

The invention is an ion-assisted deposition technique for the planarization of topological defects. One application of this planarization technique is to mitigate the effects of small particle contaminants on reticles for extreme ultraviolet (EUV) lithography. Reticles for EUV lithography will be fabricated by depositing high EUV reflectance Mo/Si multilayer films on superpolished low-thermal-expansion glass substrates. Any topological substrate defects can nucleate unacceptable (“critical”) defects in the reflective Mo/Si coatings. A Mo/Si planarization process has been developed in which a secondary ion source is used to etch the Si layers in between each deposition of a Mo/Si bilayer; substrate surfaces with 50 nm diameter particulates are planarized to produce topological defects with heights of ˜1 nm, rendering them harmless to the lithographic process. This can be achieved while maintaining a low RMS roughness of the coating surface and also a high EUV reflectivity for the Mo/Si; the latter enables the planarization layer to also be used as the reflective coating.

Reticles for EUV lithography have stringent thickness uniformity requirements for the Mo/Si coatings; the conditions for obtaining excellent thickness uniformity usually require off-normal incidence deposition, in which defect smoothing is not optimal. The present disclosure demonstrates that the use of ion-assistance enables highly uniform coatings with excellent planarization properties to be produced simultaneously. The ion-assisted Mo/Si process has added advantages such as (a) the high-spatial frequency roughness of substrates can be reduced, (b) the coating stress can be reduced, and (c) there is the possibility of producing smooth Mo/Si buffer layer coatings with a tensile stress to compensate for the compressive stress of the reflective Mo/Si coating. The present disclosure also demonstrates that excellent planarization can be achieved by employing the ion-assisted process with pure Si films.

This invention fits within the scope of the national nanotechnology initiative. There is also a strong commercial driving force for increased miniaturization in electronic devices, and hence an extreme ultraviolet lithography (EUVL) system has significant commercial potential. A critical element of this technology is the reticle, and this invention addresses one of the most challenging problems in the development of the commercially viable EUVL reticle.

### BRIEF DESCRIPTION OF THE DRAWINGS

FIG. 1 shows an example of the deposition apparatus used for ion-assisted Mo/Si deposition.

FIGS. 2A-C illustrate the steps of an embodiment of the process used for ion-assisted Mo/Si deposition

FIG. 3A shows the cross-sectional surface profile as measured by atomic force microscopy for an uncoated Au sphere of diameter ˜50 nm and the top surface of a Mo/Si multilayer film deposited on the same Au spheres with and without ion assistance.

FIG. 3B is a theoretical curve for the printability of a Mo/Si multilayer defect as a function of the defect height and coated full-width-at-half-maximum (FWHM). The ion-assisted process results in a benign, nonprintable defect.

FIG. 4 shows that the final height of a defect nucleated by a 50-nm diameter particle on the substrate and coated with a pure Si film using the ion-assist technique was 1.5 nm. In comparison, the final height of the same defect coated with a Mo/Si multilayer using the ion-assist technique was 1.0 nm.

FIG. 5A shows the cross-sectional surface profile as measured by atomic force microscopy for Mo/Si films deposited on ˜50 nm Au spheres for conditions yielding (a) excellent uniformity and poor smoothing, (b) modest smoothing and poor uniformity, (c) excellent smoothing and excellent uniformity.

FIG. 5B shows the normalized thickness of Mo/Si films as a function of the distance from the center for conditions yielding (a) excellent uniformity and poor smoothing, (b) modest smoothing and poor uniformity and (c) excellent smoothing and excellent uniformity.

### DETAILED DESCRIPTION OF THE PREFERRED EMBODIMENTS

The invention is an ion-assisted deposition process to deposit a film to smooth over substrate particles and asperities, thus planarizing the surface to the nanometer-scale regime. The term “ion-assisted” herein means direct ion bombardment either during film deposition or in between the deposition of thin (<100 nm thick) layers. The latter process is also sometimes referred to as “ion polishing”. This planarization process will be particularly useful in preparing nearly defect-free reticle substrates for extreme ultraviolet lithography. To be effective, the multilayer buffer-layer must smooth over the surface topology due to defects of at least several tens of nm in size, and the multilayer deposition process should not add significant amounts of particles.

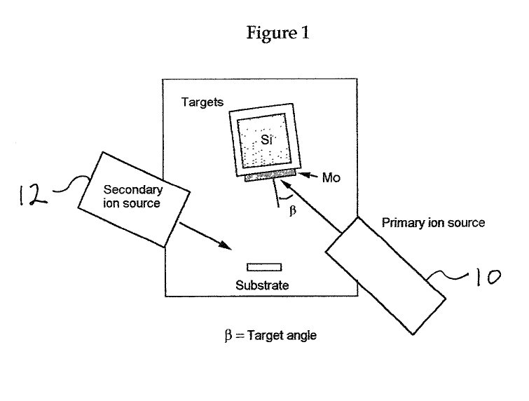

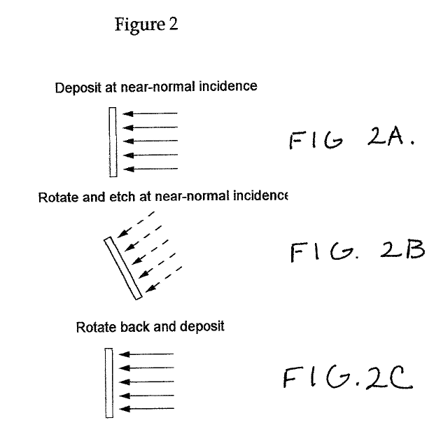

The invention was demonstrated using Mo/Si multilayer films and pure Si films. A commercially available ion beam sputter deposition system 10 equipped with a secondary ion source 12 was used, as shown in FIG. 1. The deposition process consisted of sequential deposition and etch steps, as shown schematically in FIGS. 2A-C. Each layer of a multilayer film was deposited by ion beam sputtering, usually at near-normal incidence, and then subsequently etched by the secondary ion source. Near-normal incidence deposition is preferable based on previous work [Mirkarimi and Stearns, Appl. Phys. Lett. 77, 2243 (2000)] showing that it enhances smoothing. However, off-normal incidence deposition was also used when optimal coating thickness uniformity was required.

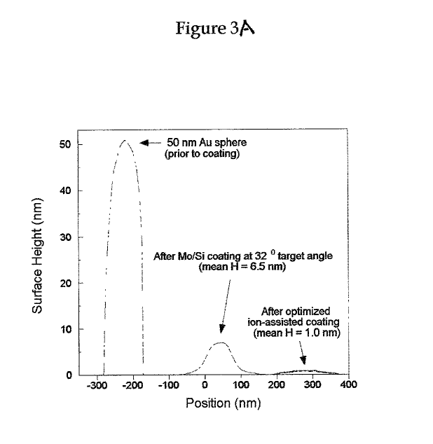

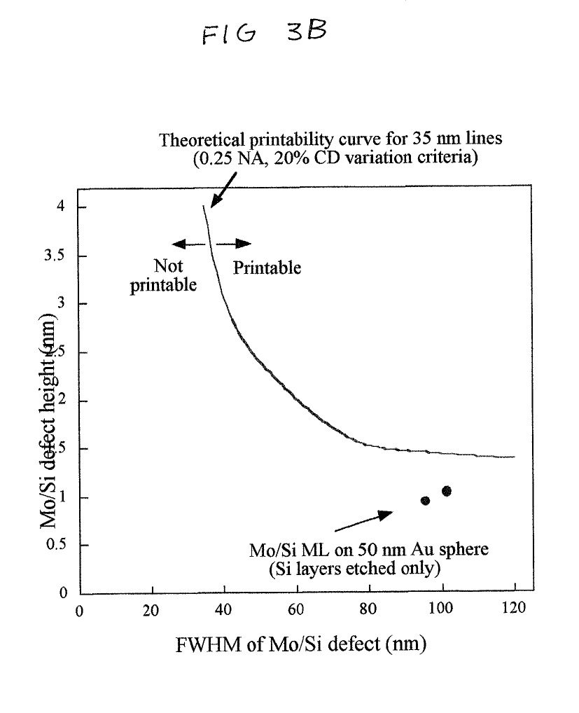

For the tests, the Mo/Si multilayer was deposited on ˜50 nm diameter Au nanospheres using a technique described elsewhere [Mirkarimi et al., J. Vac. Sci. Technol. B 19, 628-633 (2001)] incorporated herein by reference. The Mo/Si films had a bilayer period thickness of ˜7 nm, where the Mo thickness was ˜2.8 nm and the Si thickness was ˜4.2 nm. Ten Mo/Si bilayers with no etching were deposited followed by 40.5 Mo/Si bilayers with etching. The initial ten bilayers were deposited without etching to ensure that the Au spheres were not sputtered for the tests. For the ion beam sputter deposition tests the primary ion source beam energy was 800 eV, and for the etching, the secondary ion source beam energy was 250 eV; however, primary ion beam source energies in the range of 400-2000 eV and secondary ion beam source energies in the range of approximately 50-2000 eV may also work well. Argon was used as the source gas for both ion sources however source gases such as Kr, Ne and Xe are expected to also work. Initial work focused on finding the optimal smoothing conditions for the tests: the optimized conditions obtained resulted in ˜50 nm spheres being smoothed to a mean defect height of 2.7 nm at the surface of the Mo/Si film. See U.S. Pat. No. 6,319,635 B1, titled “Mitigation Of Substrate Defects In Reticles Using Multilayer Buffer Layers” incorporated herein by reference and [Mirkarimi et al., IEEE J. Quant Elec., 37, 1514 (2001)]. An investigation was conducted to determine whether the etching of the Si or Mo layers had a greater impact on the smoothing process and it was observed that the etching of the Si layers played a significantly greater role in particle smoothing than did the etching of the Mo layers. Optimization of the Si etching process resulted in a further improvement, as detailed in Table 1 below and illustrated in FIG. 3A. Au spheres with a height of ˜50 nm were smoothed to a mean height of ˜6.5 nm under optimal Mo/Si deposition conditions for smoothing. However, when the optimized ion-assisted smoothing process, i.e., sequential etching of the Si layers, is implemented, the ˜50 nm high spheres are smoothed to a mean defect height of 0.92-1.03 nm, a significant improvement. A process whereby the Mo layers are etched yields a mean defect height of 9.8 nm, further demonstrating the importance of Si etching in the planarization process. The Mo-etching process also yields a multilayer surface with a much higher high-spatial frequency roughness, which is not desirable. One of the likely reasons for the difference in the smoothing properties between films with etched-Mo versus etched-Si is that the Si films are amorphous whereas the Mo films are polycrystalline. Particular crystalline directions in the Mo films can be preferentially etched, leading to a greater surface roughness. This is not to say that an optimization of the etching conditions (angle, energy, etc) cannot lead to improved smoothing properties over that reported in Table I; however, it is unlikely that the smoothing properties of etched polycrystalline materials such as Mo will meet or exceed the smoothing properties of etched amorphous materials such as Si.

Table 1 shows defect measurements for Mo/Si multilayer films deposited with the Si-etching-only ion-assisted process and for the Mo-etching-only process. The deposition and etching occurred at normal incidence (i.e., parallel to the substrate normal), and the etched layers had ˜1.4 nm of material removed per layer. The high roughness of the Mo-etched Mo/Si makes it difficult to accurately assess the defect radius and volume.

| | Number of | Mean | Mean | Full-width- | Surface |
|---|---|---|---|---|---|
| | Mo/Si | defect | defect | at-half- | roughness |
| | defects | height | volume | maximum | of Mo/Si |
| Description | measured | (nm) | (nm³) | (nm) | (nm) |
| Mo/Si with | 32 | 0.92 nm | 9,535 | 95.5 | 0.084 |
| each Si | | | | | |
| layer | | | | | |
| etched | | | | | |
| Same as | 32 | 1.03 nm | 11,988 | 101.3 | 0.087 |
| above | | | | | |
| Mo/Si with | 22 | 9.8 nm | — | — | 0.436 |
| each Mo | | | | | |
| layer | | | | | |
| etched | | | | | |

It is expected that the technique will work for etching at angles other than at near-normal incidence. For example, a Mo/Si multilayer film was deposited where the ion beam for the etch steps were directed at an angle of 84 degrees from the substrate normal (i.e., at grazing incidence); in this test 50 nm Au spheres were smoothed to a mean defect height of 1.62 nm. Therefore, significant planarization is possibly at other etching angles; however, the observed planarization is not as great as that achieved with near-normal incidence etching.

The optimal results achieved to date for the ˜7 nm bilayer period Mo/Si multilayer films was for >1.4 nm of additional Si to be deposited and etched away. Significant smoothing was also achieved for smaller amounts of etching; for example, a sphere with a 50 nm height was smoothed to a height of ˜1.25 nm by Mo/Si deposition when ˜1.0 nm of material was etched from each Si layer.

An important application for this invention is the planarization of reticle substrate surfaces for EUV lithography. Deposition of a standard reflective Mo/Si multilayer film on top of a 50 nm Au particle yielded a Mo/Si defect (bump) with a mean height of 6.5 nm and a mean full-width-at-half-maximum (FWHM) of 48.5 nm. FIG. 3B shows simulations from a model by Gullikson et al. [Gullikson et al., JVST B, January/February 2002], and according to the theoretical printability curve the 6.5 nm high Mo/Si defects should print in a EUV lithography tool. However, the 50 nm particle smoothed using the Mo/Si deposition process where the Si layers are etched yielded mean defect heights of 0.92 nm and 1.03 nm and mean FWHM's of 95 and 101 nm, respectively. As shown on FIG. 3B, these planarized defects should be rendered nonprintable according to the EUVL printability simulations.

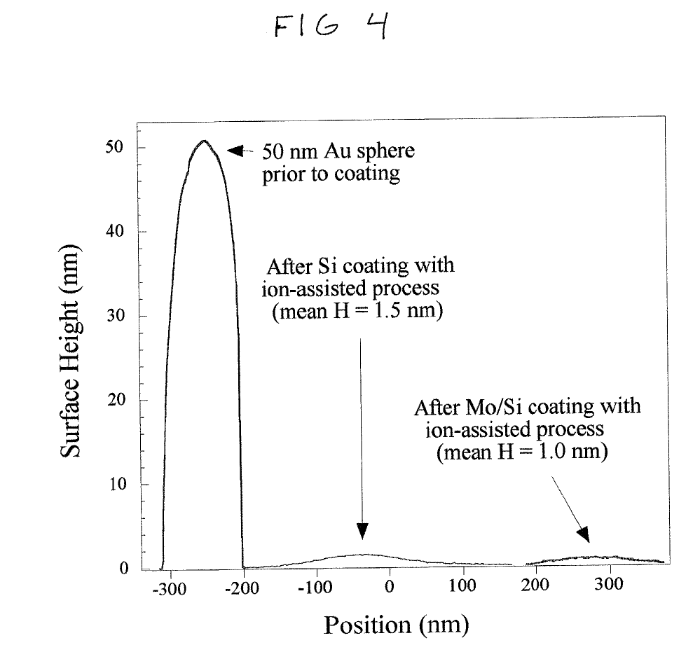

The ion-assisted process described herein does not only improve the particle-smoothing properties of multilayer films, but also enhances the particle-smoothing properties of homogeneous films. For example, a ˜280 nm thick pure Si film was deposited on ˜50 nm Au spheres in which thin Si layers were successively deposited and etched. The resulting thickness of each Si layer in the Si film was ˜4.2 nm, so as to be comparable to the thickness of the Si layers in a Mo/Si multilayer film. The resulting mean defect height was 1.54 nm; this is not as good as the ˜1.0 nm defect height achieved with the ion-assisted Mo/Si process on the same size Au spheres, but is much more desirable than the 34.1 nm mean defect height observed by depositing the same thickness Si film on the same size Au spheres with no ion assistance. FIG. 4 shows that the final height of a defect nucleated by a 50-nm diameter particle on the substrate and coated with a pure Si film using the ion-assist technique was 1.5 nm. In comparison, the final height of the same defect coated with a Mo/Si multilayer using the ion-assist technique was ˜1.0 nm. If the ion-assisted film used to smooth over substrate asperities increases the high-spatial frequency roughness of the surface relative to the roughness of a film with no ion-assistance, it will degrade the EUV reflectivity of the multilayer overcoat, as discussed in U.S. Pat. No. 6,319,635, incorporated herein by reference. This is a concern since the ion etching could roughen the film and render the technique useless. The high-spatial frequency roughness is typically measured on an atomic force microscope, for the multilayer films with the smoothing properties described in FIGS. 3A and 3B the high-spatial frequency roughness (as measured in 2 μm×2 μm scans) was <0.087 nm rms, which is lower than the Mo/Si multilayers deposited without ion-assistance, where the roughness is >0.100 nm rms. Thus the technique appears to decrease the high-spatial frequency roughness, which is an added advantage of this technique. As an additional test a multilayer with optimal particle-smoothing properties was deposited on a substrate with a spatial frequency roughness of 0.33 nm rms and the surface of the coating afterwards was 0.17 nm rms. Previous work on magnetron sputtered Mo/Si films [Mirkarimi et al. Applied Optics 39, 1617 (2000)] indicates that a ˜3.5% improvement in EUV reflectivity is possible when the substrate roughness is decreased from 0.33 nm to 0.17 nm. This work also shows promise for the reduction of high-spatial frequency roughness in surfaces such as EUVL projection optics, where the surface finish of the substrates is of great concern.

If the multilayer optimized for smoothing also has a relatively high EUV reflectance, it is possible to have the multilayer smoothing layer also serve as the high-reflectivity coating, simplifying the manufacturing process and increasing the chances of making a nearly defect-free EUVL mask blank (since the thicker the coating the greater the chances of defects being generated during the coating process). When measuring the reflectivity of a 50 bilayer period Mo/Si multilayer film deposited with the ion-assisted, Si-etching only process used to obtain optimal smoothing; the reflectivity was ˜66.2% and at a wavelength (λ) of 13.68 nm. A similar Mo/Si film deposited without ion-assistance yielded a reflectivity of 67.1% at ,λ=13.47 nm. This shows that there is little change in EUV reflectivity by using an ion-assisted process and that relatively high absolute values for the EUV reflectivity can be achieved.

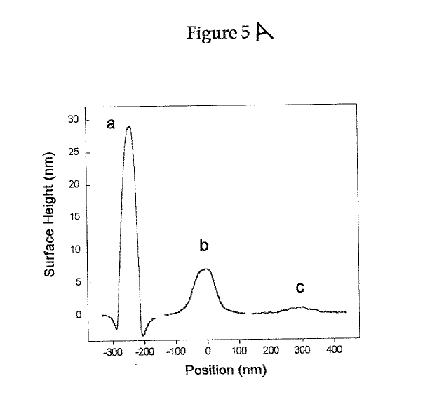

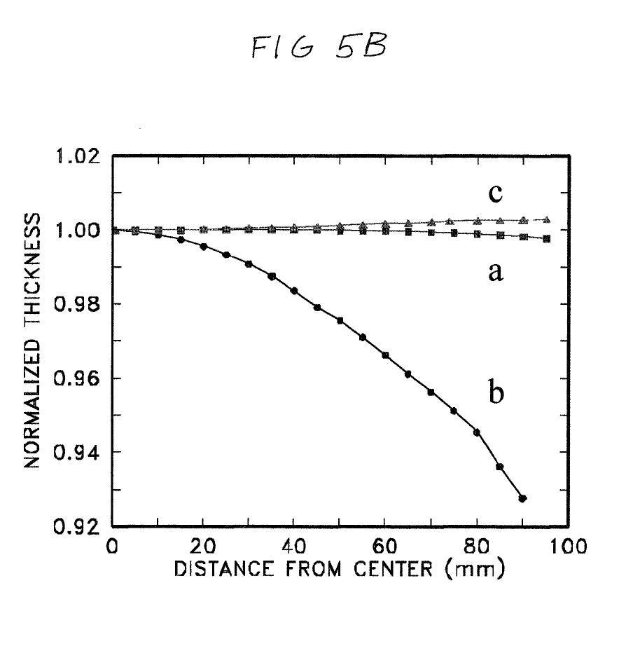

For EUV lithography there are stringent requirements for the uniformity of the reflected wavelength (λ) and hence the multilayer period thickness, on the mask substrate; if the smoothing layer is to be used as the reflective layer then it must meet these coating thickness uniformity requirements. Without the use of ion-assistance several geometric positions were found in the deposition chamber which yield uniformity at or beyond specifications for EUVL reticles; however, these positions yield coatings with sub-optimal smoothing properties. For example, in the position for good uniformity, spheres of ˜50 nm in height are smoothed to only ˜27 nm in height, compared to a ˜6.5 nm height in the position optimized for good particle smoothing. Thus it appears that optimal smoothing and uniformity cannot be achieved simultaneously. However, when the present ion-assisted process is utilized in the position optimized for good uniformity, the height of the ˜50 nm Au spheres is reduced to ˜1 nm, i.e., the ion assisted process enables optimal smoothing and uniformity to be achieved simultaneously. FIGS. 5A and 5B show the measured surface defect profile and wavelength uniformity for multilayer coatings deposited in geometric positions providing (a) excellent uniformity/poor smoothing (b) modest smoothing/poor uniformity and (c) excellent smoothing/excellent uniformity, where (c) is enabled by the use of the ion-assisted process described herein.

If the ion-assisted process caused a substantial increase in the film stress it would make the technique less desirable; for example, in EUV lithography the reticle must meet strict flatness specifications, and film stress induces curvature in the reticle. A measurement of the stress of a Mo/Si multilayer film with optimal smoothing properties was made, producing a value of 302 MPa (compressive), which is lower than the measured value of 413 MPa (compressive) for a comparable Mo/Si multilayer deposited with no ion assistance. Thus the film stress appears to decrease with the ion-assisted process. There are likely other ways that this invention could be used to mitigate the further reduce the stress in the multilayer coating. For example it has been shown previously that the stress in Mo/Si multilayer films can be made tensile by making the Mo fraction >70% [P. B. Mirkarimi, Opt Eng. 38,1246-1259 (1999)]. It has also been shown that by using a buffer-layer with a tensile stress, the effect of compressive stress in Mo/Si films can be counteracted [P. B. Mirkarimi and C. Montcalm, U.S. Pat. No. 6,011,646; P. B. Mirkarimi, Opt Eng. 38, 1246-1259 (1999)]. The Mo/Si film with a high Mo fraction cannot generally be used as a buffer-layer, since the thicker Mo produces a surface that is too rough for EUV lithography specifications. However, with this technique it should be possible to generate a high-Mo-fraction Mo/Si multilayer film that is sufficiently smooth to use as a buffer-layer for compensating the compressive stress of the reflective coating.

The foregoing description of the invention has been presented for purposes of illustration and description and is not intended to be exhaustive or to limit the invention to the precise form disclosed. Many modifications and variations are possible in light of the above teaching. The embodiments disclosed were meant only to explain the principles of the invention and its practical application to thereby enable others skilled in the art to best use the invention in various embodiments and with various modifications suited to the particular use contemplated. The scope of the invention is to be defined by the following claims.

We claim:

1. A method for the mitigation of topological defects of an optical material, wherein said optical material comprises at least one layer of amorphous material, the method comprising planarizing with an ion beam only said at least one layer of amorphous material.

2. The method of claim 1, wherein said at least one layer of amorphous material comprises at least one layer of silicon.

3. The method of claim 1, wherein said at least one layer of amorphous material comprises a layer of silicon on a substrate.

4. The method of claim 1, further comprising depositing said at least one layer of amorphous material onto a substrate prior to the step of planarizing.

5. The method of claim 4, wherein said at least one layer of amorphous material comprises a plurality of layers of amorphous material, the method further comprising planarizing each layer of said plurality of layers of amorphous material.

6. The method of claim 4, wherein the step of depositing said at least one layer of amorphous material is carried out with a primary ion beam and wherein the step of planarizing is carried out with a secondary ion beam.

7. The method of claim 1, wherein said optical material comprises a bi-layer of optical material on a substrate, wherein said at least one layer of amorphous material forms one layer of said bi-layer and has an index of refraction that is less than a material that forms another layer of said bi-layer.

8. The method of claim 2, wherein said optical material comprises a bi-layer of optical material on a substrate, wherein said at least one layer of silicon forms one layer of said bi-layer and wherein molybdenum forms another layer of said bi-layer.

9. The method of claim 2, wherein said optical material comprises a bi-layer of optical material on a substrate, wherein said at least one layer of silicon forms one layer of said bi-layer and wherein beryllium forms another layer of said bi-layer.

10. The method of claim 2, wherein said at least one layer of silicon is an element of an EUV reticle.

11. The method of claim 1, wherein said at least one layer of amorphous material is deposited by ion beam sputtering at near-normal incidence and then subsequently etched by a secondary ion source at near-normal incidence.

12. The method of claim 2, wherein said at least one layer of silicon is deposited by ion beam sputtering with a primary ion beam at an energy within a range from about 400-2000 eV.

13. The method of claim 9, wherein the step of planarizing is carried out with an ion beam having an ion beam energy in the range from about 50-2000 eV.

14. The method of claim 6, wherein at least one of said primary ion beam and said secondary ion beam comprises a source gas selected from the group consisting of Argon, Krypton, Neon and Xenon.

15. The method of claim 1, wherein the step of planarizing includes directing an ion beam onto said at least one layer of amorphous material to remove a fraction of the layer between the values of 0.05 and 1.

16. An EUV reticle, comprising a bi-layer of optical material on a substrate, wherein said at least one layer of amorphous material forms one layer of said bi-layer and has an index of refraction that is less than a material that forms another layer of said bi-layer, wherein only said at least one layer of amorphous material has been planarized with an ion beam.

17. The apparatus of claim 16, wherein said at least one layer of amorphous material comprises at least one layer of silicon.

18. The apparatus of claim 16, wherein said at least one layer of amorphous material comprises a plurality of layers of amorphous material, wherein each layer of said plurality of layers of amorphous material has been planarized.

19. The apparatus of claim 16, wherein said at least one layer of silicon forms one layer of said bi-layer and wherein molybdenum forms another layer of said bi-layer.

20. The apparatus of claim 16, wherein said at least one layer of silicon forms one layer of said bi-layer and wherein beryllium forms another layer of said bi-layer.
